(19) United States
(12) Patent Application Publication
(10) Pub. No.: US 2009/0317974 A1
(43) Pub. Date: Dec. 24, 2009

(54) POLISHING COMPOSITION FOR SILICON WAFER, POLISHING COMPOSITION KIT FOR SILICON WAFER AND METHOD OF POLISHING SILICON WAFER

(75) Inventors: Naoyuki Iwata, Tokyo (JP); Isao Nagashima, Tochigi-ken (JP)

Correspondence Address: Workman Nydegger;1000 Eagle Gate Tower, 60 East South Temple, Salt Lake City, UT, 84111, US

(73) Assignee: DuPont AirProducts NanoMaterials Limited Liability Company, Tempe, AZ (US)

(21) Appl. No.: 12/282,969

(22) PCT Filed: Oct. 18, 2006
(86) PCT No.: PCT/JP2006/320750

§ 371 Date: May 6, 2009

(30) Foreign Application Priority Data
Mar. 15, 2006 (JP) 2006-071503

(51) Int. Cl. H01L 21/302; C09K 13/02; C09K 13/00

(52) U.S. Cl. 438/693; 252/79.5; 252/79.1; 257/E21.214

(57) ABSTRACT

The present invention provides a polishing composition which can remove a natural oxidized layer on a silicon wafer and can efficiently polish the silicon wafer. The polishing composition of the present invention comprises colloidal ceria and an alkaline polishing composition. The polishing composition of the present invention may further comprise a chelating agent. The present invention includes a polishing method comprising removing an oxidized layer with colloidal ceria; a polishing method comprising removing an oxidized layer with colloidal ceria and polishing a silicon wafer with an alkaline polishing composition; and a polishing method comprising polishing a silicon wafer with a polishing composition comprising colloidal ceria and an alkaline polishing composition. Further, the present invention relates to a polishing composition kit comprising colloidal ceria and an alkaline polishing composition.

### TECHNICAL FIELD

This invention relates to a polishing composition for a silicon wafer, a polishing composition kit for a silicon wafer and a method of polishing a silicon wafer.

### BACKGROUND ART

In a polishing process of a semiconductor, particularly a silicon wafer, a polishing composition containing colloidal silica as abrasive grains has been in much use (for example, Japanese Patent Publication No. 61-38954 (Patent Document 1)). With recent high integration of a silicon device, the restriction to contamination or defects of the polished silicon wafer has been increasingly severe. For example, contamination due to minute amounts of metals remaining on the polished silicon wafer or occurrence of flaws due to an agglomerate of silica contained in an abrasive has become of a significant issue and therefore, deterioration of a yield ratio in a device manufacturing process attributable to such contamination or defect is unavoidable.

It is found out that the minute amounts of the metals remaining in the polished silicon wafer are attributable to metals contained in a polishing composition, and most of the metal impurities derive from colloidal silica. Therefore, it is required to reduce a content of the metal impurities of the polishing composition, particularly a content of impurities of colloidal silica. In response to this demand, there is proposed a method of using a polishing composition containing the colloidal silica with a high purity (for example, see Japanese Patent Laid-Open No. 11-214338 (Patent Document 2)). However, such a polishing composition with a high purity is generally expensive and therefore, the problem with costs occurs.

Therefore, there is proposed a method of polishing a silicon wafer with a polishing composition which does not substantially contain colloidal silica contained in the conventional polishing composition (for example, see Japanese Patent Laid-Open No. 62-259769 (Patent Document 3)). However, since the polishing composition which does not substantially contain the colloidal silica has no function of removing an oxidized layer (hereinafter, also called natural oxidized layer) generated on a silicon wafer surface as a polished article, the polishing can not be performed substantially.

For the purpose of removing a natural oxidized layer, although it is an example used in a polishing process, there is the example that an the natural oxidized layer is removed with a HF solution before the polishing process and thereafter, the polishing is performed with a polishing composition which does not substantially contain colloidal silica (for example, see Japanese Patent Laid-Open No. 2002-16025 (Patent Document 4)). However, the process of removing the natural oxidized layer with the HF solution is complicated and the silicon wafer on which the natural oxidized layer is removed in the process of removing the natural oxidized layer with the HF solution has a surface which is unprotected in the duration until the silicon wafer is transferred to the next polishing process. Therefore, the silicon wafer is exposed to various contaminations. The complicated situation of the use of HF or dangerous situation against various contaminations is true of precision polishing, as well as rough polishing.

Patent Document 1: Japanese Patent Publication No. 61-38954

Patent Document 2: Japanese Patent Laid-Open No. 11-214338

Patent Document 3: Japanese Patent Laid-Open No. 62-259769

Patent Document 4: Japanese Patent Laid-Open No. 2002-16025

### DISCLOSURE OF THE INVENTION

An object of the present invention is to provide a polishing composition which can remove a natural oxidized layer of a semiconductor wafer, particularly a silicon wafer and subsequently efficiently performs polishing of the silicon, or can efficiently perform removal of a natural oxidized layer and polishing of a semiconductor wafer simultaneously. Further objects of the present invention are to provide a method of polishing a silicon wafer using this polishing composition and to provide a kit for providing this polishing composition. A yet further object of the present invention is to provide a polishing composition having trace amounts of metal impurities. Further, a still yet further object of the present invention is to provide a polishing composition which can reduce metal impurities in a silicon wafer after polishing and flaws on a silicon wafer surface after polishing.

The present invention is made in view of the foregoing problems and relates to a polishing composition for a silicon wafer which comprises colloidal ceria including cerium oxide and water, and an alkaline polishing composition including an alkaline substance and water. The polishing composition of the present invention may contain a chelating agent. In the present invention, the alkaline substance is preferably selected from N-(2-aminoethyl)ethanolamine, piperazine, 2-aminoethanol, ethylenediamine, sodium hydroxide, potassium hydroxide, tetramethylammonium hydroxide, sodium carbonate or potassium carbonate, and the chelating agent is preferable selected form ethylenediamine tetraacetic acid, diethylenetriamine pentaacetic acid, nitrilotriacetic acid, N-hydroxyethylethylenediamine triacetic acid or hydroxyethyliminodiacetic acid. The polishing composition preferably has a pH of 10.5 to 12.5. The polishing composition of the present invention has a concentration of cerium oxide having 0.0025 to 1 parts by weight based on 1000 parts by weight of the composition at a use point of the polishing composition.

The present invention provides a polishing method of a silicon wafer. The polishing method of the present invention includes a polishing method of removing an oxidized layer on a silicon wafer surface (first embodiment), and a polishing method of performing a polish of a silicon wafer including removal of an oxidized layer (second and third embodiments).

The polishing method according to the first embodiment comprises a step of polishing a silicon wafer surface with colloidal ceria including cerium oxide and water. The polishing method according to the second embodiment comprises steps of removing an oxidized layer on the silicon wafer surface by polishing the silicon wafer surface with colloidal ceria including cerium oxide and water, and polishing subsequently the silicon wafer with an alkaline polishing composition including an alkaline substance and water. The polishing method according to the third embodiment comprises a step of polishing a silicon wafer with a polishing composition for the silicon wafer which comprises colloidal ceria including cerium oxide and water, and an alkaline polishing composition including an alkaline substance and water.

The present invention further provides a composition kit for polishing a semiconductor wafer. This kit may comprise colloidal ceria including cerium oxide and water, and an alkaline polishing composition including an alkaline substance and water. Further, a chelating agent may be included to at least one of the colloidal ceria and the alkaline polishing composition in this kit. In the kit of the present invention, the alkaline substance is preferably selected from N-(2-aminoethyl)ethanolamine, piperazine, 2-aminoethanol, ethylenediamine, sodium hydroxide, potassium hydroxide, tetramethylammonium hydroxide, sodium carbonate or potassium carbonate, and the chelating agent is preferable selected from ethylenediamine tetraacetic acid, diethylenetriamine pentaacetic acid, nitrilotriacetic acid, N-hydroxyethylethylenediamine triacetic acid or hydroxyethyliminodiacetic acid.

By using the polishing composition of the present invention, the removal of the natural oxidized layer on the silicon wafer and the polish of the silicon wafer can be performed extremely effectively. By performing the polish with the colloidal ceria and the alkaline polishing composition including the alkaline substance, the natural oxidized layer on the silicon wafer can be removed and also the polish of the silicon wafer can be performed without causing metal contamination and surface defects. Further, according to the polishing method of the present invention, it is possible to efficiently remove the natural oxidized layer on the silicon wafer. In addition, according to the polishing method of the present invention, the natural oxidized layer on the silicon wafer can be removed and also the polish of the silicon wafer can be performed without causing the metal contamination and the surface defect.

### BEST MODE FOR CARRYING OUT THE INVENTION

The present invention relates to a polishing composition for a semiconductor wafer, and in particular to a polishing composition for a silicon wafer. The present invention relates to a polishing composition in general used for a primary polishing of a semiconductor wafer.

A polishing composition for a silicon water in a first embodiment of the present invention comprises colloidal ceria including cerium oxide and water, and a polishing composition including an alkaline substance and water. In the present specification, colloidal ceria means a dispersant formed by dispersing cerium oxide powder in water.

The polishing composition of the present invention comprises cerium oxide. Since it is conventionally considered that polishing a silicon wafer with cerium oxide causes flaws thereon, the cerium oxide is considered to be unsuitable for polishing the silicon wafer. Therefore, the cerium oxide has not been so far used in the polishing composition for the silicon wafer. The present invention is made based upon the finding that the cerium oxide can efficiently remove an oxidized layer (natural oxidized layer) generated on a surface of a silicon wafer. The polishing composition of the present invention can efficiently remove the natural oxidized layer by using the polishing composition in a state of containing minute amounts of the cerium oxide upon polishing.

That is, in the present invention, the cerium oxide serves for removing the natural oxidized layer therewith, and water has a function of supplying the cerium oxide and the alkaline substance on a contact surface between a pad and a semiconductor wafer in a polishing process.

The polishing composition for the silicon wafer of the present invention may further comprise a chelating agent in the aforementioned polishing composition for the silicon wafer. The chelating agent aims at preventing contamination of a semiconductor wafer due to a metal.

The polishing composition of the present invention does not comprise the colloidal silica and therefore, the contamination of the metal impurities is extremely small. In consequence, it is not particularly required to add a chelating agent for trapping metal impurities. However, there is the possibility for metal impurities to be mixed in the manufacture or the use of the polishing composition. Therefore, it is preferable to use the chelating agent for trapping the metal impurities. Use of the chelating agent causes metal ions existing in the polishing composition to react to the chelating agent, forming complex ions thereby to effectively prevent metal contamination to a silicon wafer surface.

Hereinafter, each of components of the polishing composition and a preparation method of a polishing composition will be explained.

(Components in a Polishing Composition)

(1) Colloidal Ceria

The polishing composition of the present invention uses colloidal ceria including cerium oxide powder and water. The colloidal ceria may be prepared by dispersing the cerium oxide in the water or the colloidal ceria prepared in advance by mixing the cerium oxide with the water maybe purchased. The colloidal ceria may be available from, for example, Nayacol Company.

(1-1) Cerium Oxide

The cerium oxide contained in the colloidal ceria has an average particle diameter of 50-500 nm, preferably 80-250 nm. If the average particle diameter of the cerium oxide is less than 50 nm, a removal efficiency of the natural oxidized layer deteriorates. If the average particle diameter of the cerium oxide is more than 500 nm, flaws tend to remain on the silicon wafer after polishing. Therefore, the cerium oxide having the average particle diameter outside the range of 50-500 nm is not effective.

An amount of the cerium oxide is, for example upon polishing a silicon wafer, in a range of 2.5 ppm to 1000 ppm (0.0025 to 1 parts by weight to 1000 parts by weight of a polishing composition) in a state where the polishing composition is diluted for use in an actual polishing process (hereinafter, also called a use point of polishing), preferably 2.5 ppm to 250 ppm (0.0025 to 0.25 parts by weight to 1000 parts by weight of a polishing composition). If an amount of the cerium oxide is less than 2.5 ppm, the removal efficiency of the natural oxidized layer deteriorates. If an amount of the cerium oxide is more than 1000 ppm, the removal of efficiency of the natural oxidized layer improves, but the economical efficiency deteriorates.

In this way, it is preferable that in the present invention, the colloidal ceria includes minute amounts of the cerium oxide in the state where the polishing composition is diluted for use in the actual polishing process.

(2) Water

The present invention uses water as a medium. It is preferable that impurities in the water are reduced as much as possible. For example, the present invention may use deionized water in which ion impurities are removed with an ion exchange resin. Further, the present invention may use water which is further passed the deionized water through a filter to remove suspended solids, or distilled water. It should be noted that in the present specification, there is a case where water in which these impurities are reduced as much as possible is called simply “water” or “pure water”. Unless explicitly described, “water” or “pure water” means the water in which these impurities are reduced as much as possible.

(3) Alkaline Polishing Composition

The compound of the present invention comprises an alkaline polishing composition including an alkaline substance and water. It should be noted that the water used as the medium is as described above.

(3-1) Alkaline Substance

The alkaline substance is preferably selected from N-(2-aminoethyl)ethanolamine, piperazine, 2-aminoethanol, ethylenediamine, sodium hydroxide, potassium hydroxide, tetramethylammonium hydroxide, sodium carbonate or potassium carbonate. In the present invention, these alkaline substances may be used as single component or in combination of two or more thereof. For realizing a fast polishing speed, it is preferable to use one or more substances selected from amines such as N-(2-aminoethyl)ethanolamine, piperazine, 2-aminoethanol and ethylenediamine. An amount of the alkaline substance contained in the polishing composition is, for example, in the case of polishing the silicon wafer, preferably in a range of 100 ppm to 1000 ppm in a use point of a polishing. If an amount of the alkaline substance is less than 100 ppm, a polishing speed of the silicon is low and the polishing composition is not practical in use. If an amount of the alkaline substance is more than 10000 ppm, a rough pattern tends to be generated as if the polished surface is eroded.

(4) Chelating Agent

The compound of the present invention comprises a chelating agent as an optional component.

The chelating agent may be selected from ethylenediamine tetraacetic acid, diethylenetriamine pentaacetic acid, nitrilotriacetic acid, N-hydroxyethylethylenediamine triacetic acid or hydroxyethyliminodiacetic acid. In the present invention, these alkaline substances may be used as a single component or in combination of two or more thereof. An amount of the chelating agents contained in the polishing composition is, for example, in a case of polishing a silicon wafer, preferably in a range of 10 ppm to 1000 ppm in a use point of a polishing.

(Preparation of Polishing Composition)

The polishing composition of the present invention may be prepared by generally mixing the respective constituents with water in a desired content ratio and dispersing them in water. For example, in a case of using cerium oxide powder, the cerium oxide powder and the alkaline substance may be mixed with water so as to achieve a desired content ratio. In a case of using colloidal ceria, the colloidal ceria having a desired concentration may be prepared from the cerium oxide powder and water, and then an alkaline substance may be mixed with the colloidal ceria. Alternatively, in a case of purchasing colloidal ceria, after diluting the purchased colloidal ceria with water so as to achieve a desired concentration, and then an alkaline substance may be mixed with the diluted colloidal ceria. The above example is just one example and the mixing order of the colloidal ceria, the alkaline substance and the chelating agent may be made arbitrarily. For example, in the polishing composition, the order of dispersion of the respective components other than the alkaline substance and the chelating agent and dissolution of the alkaline substance and the chelating agent may be made arbitrarily, or the dispersion and the dissolution may be made simultaneously. Alternatively, the colloidal ceria of a desired content ratio and the alkaline polishing composition of a desired content ratio are prepared respectively, and then they may be mixed each other.

In a case where the composition of the present invention comprises a chelating agent, the chelating agent (which may be not dissolved or may be dissolved with water) may be dissolved at a desired concentration in any process of the above respective procedures.

Any method of dispersing or dissolving the above component in the water may be adopted. For example, the component may be dispersed by the stirring with a stirrer such as a blade type stirrer or the like.

The polishing composition of the present invention may be provided in a diluted state used at an actual polishing process, but may be prepared as a concentrate solution of a relatively high concentration (hereinafter, also referred to as concentrate solution simply) to be provided. Such concentrate solution is in storage or in transportation in a state of the concentrate solution and may be diluted at an actual polishing process. It is preferable that in the polishing composition of the present invention, in view of handling of the polishing composition, a polishing composition is manufactured in the form of a concentrate solution of a high concentration, is transported and is diluted at an actual polishing process.

A preferable concentration range of each aforementioned component is described as one at an actual polishing process (use point of polish). In a case of a concentrate solution, the polishing composition has necessarily each component of a high concentration. A preferable concentration of each component in the form of the concentrate solution is that cerium oxide is in a range of 0.01 to 10% by weight, an alkaline substance is in a range of 5 to 25% by weight and a chelating agent is in a range of 0.04 to 4% by weight on a basis of the total weight of the polishing composition.

The polishing composition of the present invention has preferably a pH of 10.5 to 12.5 in a case of including an alkaline substance. The polishing of the silicon wafer can be efficiently performed within this range.

Next, a polishing method of the present invention will be explained. The polishing method of the present invention is a polishing method using the polishing composition of the present invention.

A polishing method in a first embodiment is a polishing method of removing an oxidized layer on a surface of a silicon wafer. The polishing method uses colloidal ceria including cerium oxide and water as a polishing material. More specially, the polishing method comprises steps of providing colloidal ceria of a desired concentration, polishing a silicon wafer with this colloidal ceria and removing an oxidized layer formed on the surface of the semiconductor wafer.

A polishing method in a second embodiment is a polishing method of a silicon wafer using colloidal ceria and an alkaline polishing composition including an alkaline substance and water. More specially, the polishing method of the silicon wafer comprises steps of removing an oxidized layer on a silicon wafer surface by polishing the silicon wafer surface with colloidal ceria having cerium oxide and water, and polishing the silicon wafer with an alkaline polishing composition having an alkaline substance and water.

A polishing method in a third embodiment is a polishing method of a silicon wafer using a polishing composition including colloidal ceria and an alkaline polishing composition. More specially, the polishing method of the silicon wafer comprises a step of polishing the silicon wafer with a silicon-wafer polishing composition including colloidal ceria including cerium oxide and water, and an alkaline polishing composition including an alkaline substance and water.

A well-known method can be applied to a polishing steps in the polishing method of the present invention. For example, a silicon wafer held by holding means may be in close contact with a rotational board covered with a polishing cloth, which is rotated under flow of liquid of a polishing composition for the polishing. Conditions such as a flow rate of the liquid of the polishing composition and a rotational speed of a rotational plate, although depending on a polishing condition, may be set within the conventional condition range.

A polish-possible wafer in the present invention is preferably a silicon wafer, such as a single crystal silicon wafer and a polycrystalline silicon wafer. In the following explanation, an example of a silicon wafer will be explained.

In the polishing method according to the first embodiment, firstly, colloidal ceria including cerium oxide of a desired concentration is prepared based upon the procedure explained in the section of the preparation method of the aforementioned polishing composition. In a case of preparing colloidal ceria as a concentrate solution of a high concentration, the concentrate solution is diluted with water to obtain a desired concentration thereof. The dilution may be performed with a well-known mixing or dilution method such as a stirring. A content of cerium oxide powder in the colloidal ceria is preferably in a range of 2.5 to 1000 ppm in a use point of the polishing.

Next, a silicon wafer is polished in use of colloidal ceria containing minute amounts of the cerium oxide that is comprised of cerium oxide and water. A polishing process of using the colloidal ceria containing the minute amounts of the cerium oxide is suitable for, particularly, removal of a natural oxidized layer formed on a silicon wafer. Accordingly, the colloidal ceria comprising cerium oxide and water is encompassed in the present invention as a polishing composition for removal of the natural oxidized layer formed on the silicon wafer.

In the polishing method according to the second embodiment, firstly, colloidal ceria including cerium oxide of a desired concentration and an alkaline polishing composition including an alkaline substance and water are prepared based upon the procedure explained in the section of the preparation method of the polishing composition as described above. By using the prepared polishing composition, the polishing method performs the two steps of polishing procedure comprising steps of removing an oxidized layer (natural oxidized layer) on a surface of a silicon wafer by colloidal ceria and further, polishing the silicon wafer by alkaline polishing composition. It should be noted that, in a case of using the colloidal ceria as an abrasive, the reason for adopting a two step method which further polishes the silicon wafer with the alkaline polishing composition is that since the colloidal ceria can remove the natural oxidized layer, but can not polish the silicon wafer, it is required to perform the polish with the alkaline polishing composition. The removal step of the natural oxidized layer and the polishing step of the silicon wafer may be carried out of as a series of continuous processes comprising separated processes or as separated processes which are not continuous.

In a polishing method in a third embodiment, since a polishing composition of the present invention comprising colloidal ceria and an alkaline polishing composition is used, an alkaline substance is in advance included in the polishing composition. Therefore, the present polishing method can remove a natural oxidized layer and at the same time, can polish a silicon wafer.

The polishing composition of the present invention is preferably prepared by in advance mixing the respective component at a desired concentration as a polishing liquid and then, is poured to a polished material such as a silicon wafer.

Next, a polishing composition kit of the present invention will be explained.

A polishing composition kit in a first embodiment comprises colloidal ceria and an alkaline polishing composition including an alkaline substance and water.

A polishing composition kit in a second embodiment comprises colloidal ceria, an alkaline polishing composition including an alkaline substance and water, and a chelating agent.

It is preferable that in the polishing composition kit of the present invention, the colloidal ceria and the alkaline polishing composition are contained in different vessels. In addition, the chelating agent may be added to either or both of the colloidal ceria and the alkaline polishing composition.

It should be understood for those skilled in the art that the form of the polishing composition kit of the present invention is one example and may be modified variously. For example, the colloidal ceria may be contained in a vessel in a state where it is in advance mixed with water, or the cerium oxide powder and the water may be contained in a vessel as separated packages. Further, the alkaline substance of the alkaline polishing composition may contained in a vessel in a state where it is in advance mixed with water, or the alkaline substance and water may be contained in a vessel as separated packages. In addition, the respective components of the polishing composition kit of the present invention (respective materials and medium) may be contained respectively in separated vessels, or may be contained in a single vessel in a state where a part of the respective components is in advance mixed.

In the present invention, in a case where plural alkaline substances or chelating agents are included in the polishing composition, these may be contained in a single vessel or in separated vessels.

The kit of the present invention may have additional elements such as a mixing vessel, a stirring device for mixing and stirring respective components, and an instruction for use (not limited thereto) if necessary, in addition to the respective components for the polishing composition as described above.

The polishing composition kit of the present invention may be packaged, storage and transported in a dilution state used at an actual polishing process, but may be packaged separated components for a concentrate solution of the polishing composition, stored and transported. In a case of a concentrate solution, for example, a high concentration of each of the colloidal ceria, the alkaline substance and the chelating agent may be packaged, stored and transported in a desired form as a kit. The concentrate components may be mixed and diluted so as to obtain a predetermined concentration immediately before the polishing. It is preferable that in the kit of the present invention, a concentration of the cerium oxide in high concentrate included in the colloidal ceria is in a range of 0.01 to 20% by weight.

As described above, since the polishing composition, the polishing method and the polishing composition kit do not contain abrasive grains causing metal contamination or surface defects of silica or the like, the metal contamination and the surface defect are not generated. In addition, due to trace amounts of the cerium oxide, the removal of the natural oxidized layer on the silicon wafer can be performed, and the polish of the silicon wafer can be performed.

### Examples

Hereinafter, Examples of the present invention will be described. In the following Examples, unless noted otherwise, a numerical value means a part by weight. Further, the following Examples are merely illustrative of the present invention and therefore the present invention is not limited thereto.

(Polishing Method)

Two heads holding a P-type (100) silicon wafer of four inches were pressed against a rotating bed covered with an urethane based pad (SUBA600 made by Nitta Haas Co.) for pressurization, and the heads were also rotated to supply each polishing liquid listed in the following table 1, thus performing the polishing. The progress of the polishing was observed by monitoring a temperature of the pad. Before and after the polishing, a weight of the wafer was measured to calculate a polishing speed from weight reduction.

(Polishing Condition)

Pressure: 300 gr/cm²

Bed rotational number: 120 rpm

Polishing liquid supply speed: 200 ml/min

Polishing liquid temperature: about 25° C.

Pad temperature at the beginning of polishing: about 35° C.

### Examples 1 to 4

There are shown examples of a two-step polishing of a silicon wafer using colloidal ceria and an alkaline polishing composition and a polishing of a silicon wafer using only colloidal ceria.

(Preparation of Polishing Liquid)

Polishing Liquid A

Respective components shown in the following table 1 were mixed to prepare polishing liquid A.

TABLE 1

| DIW | Colloidal ceria |
|---|---|
| 1000 | 0.025 |

DIW: deionized water
Colloidal ceria: solution including 5% by weight of cerium oxide

Polishing Liquid B

Respective components shown in the following table 2 were mixed to prepare polishing liquid B (alkaline polishing composition).

TABLE 2

| DIW | EA | PD |
|---|---|---|
| 1000 | 1 | 2 |

DIW: deionized water
EA: N-(2-aminoethyl)ethanol
PD: piperazine

The aforementioned polishing conditions were used to perform the polishing of each of Examples 1 to 4 shown in Table 3 and polishing speeds were measured.

TABLE 3

| | |
|---|---|
| Example 1 | polishing was made for 20-second using polishing |
| | liquid A, and immediately after that, polishing |
| | liquid A was replaced by polishing liquid B and |
| | polishing was made for 20-minute totally. |
| Example 2 | polishing was made for 3-minute using polishing |
| | liquid A, and immediately after that, polishing |
| | liquid A was replaced by polishing liquid B and |
| | polishing was made for 20-minute totally. |
| Embodiment 3 | polishing was made for 10-minute using polishing |
| | liquid A, and immediately after that, polishing |
| | liquid A was replaced by polishing liquid B and |
| | polishing was made for 20-minute totally. |
| Example 4 | polishing was made for 20-minute using polishing |
| | liquid A (the polishing using polishing liquid |
| | B was not made). |

Result

The polishing speeds (micron/min) of the Examples 1 to 4 were as follows.

TABLE 4

| | |
|---|---|
| Example 1 | 0.72 |
| Example 2 | 0.65 |
| Example 3 | 0.38 |
| Example 4 | 0.066 |

The result shows that the polishing liquid A acts on an oxidized layer only and does not have any effect on silicon polishing.

The above result shows that the colloidal ceria removed only the oxidized layer on the silicon wafer.

### Examples 5 to 10 and Comparative Examples 1 to 5

These are examples of polishing a silicon wafer by using an liquid for polishing comprising colloidal ceria and an alkaline polishing composition. In each of the Examples 5 to 10 and the Comparative Examples 1 to 5, one head holding a silicon wafer of 6 inches was pressed for the polishing. It should be noted that comparative examples include examples of performing the polishing by using colloidal silica in place of colloidal ceria and examples of performing the polish by using an alkaline polishing composition only.

Respective components shown in the following table 5 were mixed to prepare a polishing liquid. These liquids were used to polish a silicon wafer on the above polishing conditions. The polishing time was set as 20 minutes.

TABLE 5

| | | | | Colloidal | Colloidal |
|---|---|---|---|---|---|
| | DIW | EA | PD | ceria | silica |
| Example 5 | 1000 | 1 | 2 | 0.0025 | 0 |
| Example 6 | 1000 | 1 | 2 | 0.005 | 0 |
| Example 7 | 1000 | 1 | 2 | 0.0125 | 0 |
| Example 8 | 1000 | 1 | 2 | 0.025 | 0 |
| Example 9 | 1000 | 1 | 2 | 0.05 | 0 |
| Example 10 | 1000 | 1 | 2 | 0.1 | 0 |
| Comparative | 1000 | 1 | 2 | 0 | 0 |
| Example 1 | | | | | |
| Comparative | 1000 | 1 | 2 | 0.001 | 0 |
| Example 2 | | | | | |
| Comparative | 1000 | 1 | 2 | 0 | 0.005 |
| Example 3 | | | | | |
| Comparative | 1000 | 1 | 2 | 0 | 0.05 |
| Example 4 | | | | | |
| Comparative | 1000 | 1 | 2 | 0 | 0.2 |
| Example 5 | | | | | |

DIW: deionized water
EA: N-(2-aminoethyl)ethanol
PD: piperazine (6 hydrates)
Colloidal ceria: solution including 5% by weight of cerium oxide of
Colloidal silica: solution of 50% by weight of silicon dioxide

(Result)

The time until the natural oxidized layer was removed was measured. The result is shown in Table 6.

TABLE 6

| | Time till natural | Average polishing |
|---|---|---|
| | oxidized layer is removed | speed |
| | (sec) | (micro/min) |
| Example 5 | 40 | 0.64 |
| Example 6 | 50 | 0.65 |
| Example 7 | 30 | 0.73 |
| Example 8 | 20 | 0.76 |
| Example 9 | 15 | 0.71 |
| Example 10 | 15 | 0.74 |
| Comparative | Natural oxidized layer | 0 |
| Example 1 | cannot be removed | |
| Comparative | Natural oxidized layer | 0 |
| Example 2 | cannot be removed | |
| Comparative | Natural oxidized layer | 0 |
| Example 3 | cannot be removed | |
| Comparative | Very long time as it | 0.5 |
| Example 4 | cannot measure removal of | |
| | natural oxidized layer | |
| Comparative | Very long time as it | 0.56 |
| Example 5 | cannot measure removal of | |
| | natural oxidized layer | |

The polishing composition of the present invention comprising trace amounts of cerium oxide (colloidal ceria) and alkaline polishing composition can remove the natural oxidized layer on the silicon wafer and polish the silicon wafer at the same time.

It is found out that, in Comparative Examples 3 to 5 using colloidal silica, for polishing the silicon wafer, it is required to use colloidal silica of a relatively high concentration as compared to colloidal ceria and the average polishing speed is also slower than that of the polishing composition of the present invention. It is shown that the polishing composition of the present invention comprising trace amounts of ceria and alkaline substances first removes the oxidized layer and subsequently polishes the silicon efficiently.

### Example 11 and Comparative Example 6

A concentration of metal impurities included in the polishing composition was measured. The measured polishing compositions are concentrate solutions of a polishing liquid of Example 6 and a polishing liquid of Comparative Example 5, which were measured by Agilent 7500 ICP-MS. The result is shown in Table 7.

TABLE 7

| | | Concentrate |
|---|---|---|
| | Concentrate | solution of |
| | solution of Example | Comparative Example |
| Detected elements | 6 (ppb) | 5 (ppb) |
| Fe | 50 | 7000 |
| Al | 400 | 25000 |
| Cu | 2 | 40 |
| Ni | 2 | 30 |
| Cr | 10 | 220 |
| Zn | 30 | 30 |

As shown in Table 7, the polishing composition of the present invention could reduce metal impurities as compared to the conventional polishing composition.

### INDUSTRIAL APPLICABILITY

The present invention can be applied to a field of the polishing of a semiconductor wafer.

1. A polishing composition for a silicon wafer comprising:
colloidal ceria comprising cerium oxide and water; and
an alkaline polishing composition comprising an alkaline substance and water.

2. The polishing composition for a silicon wafer according to claim 1, further comprising:
a chelating agent.

3. The polishing composition for a silicon wafer according to claim 1, wherein the alkaline substance is selected from N-(2-aminoethyl)ethanolamine, piperazine, 2-aminoethanol, ethylenediamine, sodium hydroxide, potassium hydroxide, tetramethylammonium hydroxide, sodium carbonate or potassium carbonate.

4. The polishing composition for a silicon wafer according to claim 2, wherein the chelating agent is selected from ethylenediamine tetraacetic acid, diethylenetriamine pentaacetic acid, nitrilotriacetic acid, N-hydroxyethylethylenediamine triacetic acid or hydroxyethyliminodiacetic acid.

5. The polishing composition for a silicon wafer according to claim 1, wherein the polishing composition is diluted before polishing the silicon wafer.

6. The polishing composition for a silicon wafer according to claim 1, wherein the polishing composition has a pH of 10.5 to 12.5.

7. The polishing composition for a silicon wafer according to claim 1, wherein a concentration of the cerium oxide is 0.0025 to 1 parts by weight to 1000 parts by weight of the compound in a use point of using the polishing composition.

8. A polishing method of removing an oxidized layer on a silicon wafer surface comprising:
polishing the silicon wafer surface with colloidal ceria comprising cerium oxide and water.

9. A method of polishing a silicon wafer comprising:
removing an oxidized layer on a silicon wafer surface by polishing the silicon wafer surface with colloidal ceria comprising cerium oxide and water; and
polishing the silicon wafer with an alkaline polishing composition comprising an alkaline substance and water.

10. A method of polishing a silicon wafer comprising:
polishing the silicon wafer with a silicon-wafer polishing composition comprising colloidal ceria comprising cerium oxide and water, and an alkaline polishing composition comprising an alkaline substance and water.

11. The method of polishing a silicon wafer according to claim 8, wherein the colloidal ceria and/or the alkaline polishing composition further comprises a chelating agent.

12. A polishing composition kit for a silicon wafer comprising:
colloidal ceria comprising cerium oxide and water; and
an alkaline polishing composition comprising an alkaline substance and water.

13. A polishing composition kit for a silicon wafer according to claim 12, wherein the colloidal ceria and/or the alkaline polishing composition further comprises a chelating agent.

14. A polishing composition kit for a silicon wafer according to claim 12, wherein the alkaline substance is selected from N-(2-aminoethyl)ethanolamine, piperazine, 2-aminoethanol, ethylenediamine, sodium hydroxide, potassium hydroxide, tetramethylammonium hydroxide, sodium carbonate or potassium carbonate.

15. A polishing composition kit for polishing a silicon wafer according to claim 13, wherein the chelating agent is selected from ethylenediamine tetraacetic acid, diethylenetriamine pentaacetic acid, nitrilotriacetic acid, N-hydroxyethylethylenediamine triacetic acid or hydroxyethyliminodiacetic acid.

16. A polishing composition kit for polishing a silicon wafer according to claim 12, wherein a concentration of the cerium oxide contained in the colloidal ceria is 0.01 to 20% by weight.

17. A compound kit for polishing a silicon wafer according to claim 16, wherein the polishing composition is diluted before polishing the silicon wafer.

18. The polishing composition for a silicon wafer according to claim 2, wherein the alkaline substance is selected from N-(2-aminoethyl)ethanolamine, piperazine, 2-aminoethanol, ethylenediamine, sodium hydroxide, potassium hydroxide, tetramethylammonium hydroxide, sodium carbonate or potassium carbonate.

19. The method of polishing a silicon wafer according to claim 9, wherein the colloidal ceria and/or the alkaline polishing composition further comprises a chelating agent.

20. The method of polishing a silicon wafer according to claim 10, wherein the colloidal ceria and/or the alkaline polishing composition further comprises a chelating agent.

21. A polishing composition kit for polishing a silicon wafer according to claim 13, wherein a concentration of the cerium oxide contained in the colloidal ceria is 0.01 to 20% by weight.

22. A polishing composition kit for polishing a silicon wafer according to claim 14, wherein a concentration of the cerium oxide contained in the colloidal ceria is 0.01 to 20% by weight.

23. A polishing composition kit for polishing a silicon wafer according to claim 15, wherein a concentration of the cerium oxide contained in the colloidal ceria is 0.01 to 20% by weight.
